(19) United States
(12) Patent Application Publication
(10) Pub. No.: US 2021/0289675 A1
(43) Pub. Date: Sep. 16, 2021

(54) COMPOSITION FOR SHIELDING AGAINST ELECTROMAGNETIC RADIATION

(71) Applicant: Carl Freudenberg KG, Weinheim (DE)

(72) Inventors: Volker Schroiff, Hemsbach (DE); Marco Sutter, Weinheim (DE); Matthias Hauer, Weinheim (DE); Ivan Schmalzel, Schifferstadt (DE); Rand al-Qaysi, Frankfurt am Main (DE); Bjoern Hellbach, Birkenau (DE)

(21) Appl. No.: 17/255,443

(22) PCT Filed: Jun. 27, 2019
(86) PCT No.: PCT/EP2019/067174

§ 371 Date: Dec. 23, 2020

(30) Foreign Application Priority Data
Jun. 27, 2018 (DE) 10 2018 115 503.4

(51) Int. Cl. H05K 9/00; C08K 3/04; C08K 3/08; C08K 3/013; C08K 3/40; C08G 64/02

(52) U.S. Cl. CPC H05K 9/0083; C08K 3/041; C08K 3/08; C08G 64/0241; C08K 3/40; H05K 9/009; C08K 3/013

(57) ABSTRACT

A composition for shielding against electromagnetic radiation includes: a) at least one conductive filler; and b) a polymer matrix including at least one polyurethane containing urea group. The at least one polyurethane containing urea group has a degree of branching from 0 to 20%. In an embodiment, the polymer matrix comprises at least one non-conductive matrix polymer which is different from the at least one polyurethane containing urea group.

### CROSS-REFERENCE TO PRIOR APPLICATIONS

This application is a U.S. National Phase application under 35 U.S.C. § 371 of International Application No. PCT/EP2019/067174, filed on Jun. 27, 2019, and claims benefit to German Patent Application No. DE 10 2018 115 503.4, filed on Jun. 27, 2018. The International Application was published in German on Jan. 2, 2020 as WO 2020/002511 under PCT Article 21(2).

### FIELD

The present invention relates to a composition for shielding against electromagnetic radiation, said composition comprising at least one conductive filler and a polymer matrix, to a method for producing such a composition for shielding against electromagnetic radiation, to a method for producing a substrate that is shielded from electromagnetic radiation and to the use of the shielding composition.

### BACKGROUND

Electromagnetic waves have an electrical and a magnetic field component. The waves emitted by electronic components can lead to mutual electromagnetic interference (EMI). The enormous advances in semiconductor technology have made electronic components increasingly smaller and has significantly increased their density within electronic devices. The increasing complexity of electronic systems, e.g. in areas such as electromobility, aerospace technology or medical technology, poses a great challenge to the electromagnetic compatibility of the individual components. In electric vehicles, for example, high power electric drives are integrated in the smallest space and controlled by electronic components, wherein the individual components may no longer interfere with one another. In order to achieve electromagnetic compatibility, it is known to dampen electromagnetic influences with the aid of shielding housings. The term electromagnetic compatibility (EMC) is defined, for example, in accordance with DIN VDE 0870 as the ability of an electrical device to function satisfactorily in its surroundings without unduly influencing this environment, which may also include other devices. The EMC must therefore fulfill two conditions, the shielding of the emitted radiation and the interference resistance to other electromagnetic radiation. In many countries, the corresponding devices must satisfy legal regulations. According to DIN VDE 0870, the electromagnetic influence (emi) is the effect of electromagnetic waves on circuits, devices, systems or animals. In the case of the affected objects, such an action can lead to acceptable but also unacceptable impairments, for example the functionality of devices or the danger to persons. In such cases, appropriate protective measures must be taken. The frequency range relevant for EMI shielding is generally between 100 Hz and 100 GHz. The damping achieved by shielding an irradiated electromagnetic wave is generally composed of reflection and absorption in all shielding principles. During the absorption, the electromagnetic wave loses energy, which is converted into heat energy, wherein the absorption depends on the wall thickness of the shielding material. By contrast, the reflection is independent of the material thickness, depending on the frequency range, and can occur both on the front side and on the rear side and within the material.

In the middle frequency range, the electrical conductivity behavior of the materials can generally be used to assess the shielding directly. In the lower frequency range, the relative permeability can be used to assess the shielding and the reflection and also the vibration absorption in the upper frequency range.

By way of example, Ii is known that metallic housings made of aluminum are used for shielding electromagnetic radiation. As a result of the high conductivities of the metals, good shield damping is achieved. However, the use of purely metallic shields is associated with various disadvantages, such as the complicated production by punching, bending and applying a corrosion protection, which is very cost-intensive. The freedom from design is also very limited in the case of metallic materials. Shields made of plastic can often be brought into the desired shape more easily than metals. Since most plastics are insulators, they can be made conductive by applying a surface coating, e.g. by electroplating or physical vapor deposition (PVD). However, the metallic coating of plastics generally requires a great deal of effort to prepare the components so coating adheres well.

It is furthermore known that plastic composites (composites, compounds) are used to produce electromagnetic shielding, which have a matrix of at least one polymer component and at least one filler with shielding properties. These can be used in the form of coatings, insulating tapes, moldings, etc. Electrically conductive fillers, for example, can be dispersed in a matrix of at least one non-conductive polymer to produce conductive composites.

See Geetha et al. in Journal of Applied Polymer Science, Vol. 112, 2073-2086 (2009) An overview of methods and materials for shielding electromagnetic radiation. Various plastic composites based on non-conductive polymers with a large variety of conductive fillers are mentioned. Composites based on polyurethanes or polyureas as matrix materials are not described. As an alternative, the use of conductive polymers and especially polyaniline and polypyrrole is discussed.

K. Jagatheesan et al. describe in the Indian Journal of Fiber & textile Research, vol. 39, 329-342 (2014) the electromagnetic shielding properties of composites based on conductive fillers and conductive fabrics. The focus here is on special fabrics, e.g. based on conductive hybrid yarns and a multiplicity of conductive threads for shielding a frequency range as wide as possible. Composites based on polyurethanes or polyureas are also not described.

WO 2013/021039 relates to a microwave absorbing composition containing dispersed magnetic nanoparticles in a polymer matrix. The polymer matrix contains a highly branched nitrogen-containing polymer, wherein specifically a polyurethane based on a hyperbranched melamine with polyol functionality is used.

U.S. Pat. No. 5,696,196 describes a conductive coating comprising:
a) between 7.0 and 65.0 wt % of an aqueous thermoplastic dispersion,
b) between 1.5 and 10.0 wt % of an aqueous urethane dispersion,
c) between 2.5 and 16 wt % of a coalescent solvent based on a glycol or glycol ether,
d) between 0.1 and 5.0 wt % of a conductive clay,
e) conductive metal particles selected from Cu, Ag, Ni, Au and mixtures thereof,
f) at least one defoamer, and
g) water.

The aqueous urethane dispersion can be aliphatic or aromatic, wherein it can also be a polyurethane. Information on specific di- or polyisocyanates and thus reactive compounds is not given in the description. Neorez R-966 and Bayhydrol LS-2033, both aqueous emulsion of an aliphatic urethane, are used in the exemplary embodiments.

US 2007/0056769 A1 describes a polymeric composite material for shielding against electromagnetic radiation, which comprises a non-conductive polymer, an inherently conductive polymer and an electrically conductive filler. To produce the composite, the polymer components are brought into intensive contact. Suitable non-conductive polymers are elastomers, thermoplastics and thermoset polymers, which can be selected from a variety of different polymer classes, wherein polyurethanes are also mentioned in general. Concrete compounds for producing polyurethanes are not mentioned. By way of example, according to the invention, only a polystyrene/polyaniline blend filled with nickel-coated carbon fibers is used.

KR 100901250 relates to a polyurethane composition containing zinc dioxide, which is suitable for shielding against UV radiation. This material is used, for example, to seal containers such as water tanks. The use of ZnO₂ makes it possible to dispense with organic light protection agents and also has an antibacterial effect. Furthermore, the composition of this document aims to protect materials from UV radiation. The composition according to the invention is not disclosed.

KR 1020180047410 describes a composition for electromagnetic interference shielding containing conductive and non-conductive fillers. Urea resins are generally mentioned as a possible polymer matrix. Polysiloxane is specifically used as the polymer matrix in the exemplary embodiment. The composition according to the invention is not disclosed.

The polymer matrices mentioned in the background art are still in need of improvement with regard to the complex requirements for their shielding properties and their further performance properties. The polymer matrices mentioned in the background art can generally only be loaded with a low solids content, so that limited shielding properties result. The compositions known to date either reflect only the electromagnetic radiation or the proportion of reflection to absorption is very high and cannot be controlled.

In addition, the polymer matrices known from the state of the art are also in need of improvement in terms of heat and aging resistance. Especially in the automotive field, whether it is an internal combustion engine or an electric motor, there is an urgent need for compositions for shielding against electro-magnetic radiation that are also stable at the high temperatures under the conditions of use.

### SUMMARY

In an embodiment, the present invention provides a composition for shielding against electromagnetic radiation, comprising: a) at least one conductive filler; and b) a polymer matrix comprising at least one polyurethane containing urea group, wherein the at least one polyurethane containing urea group has a degree of branching from 0 to 20%.

### BRIEF DESCRIPTION OF THE DRAWINGS

The present invention will be described in even greater detail below based on the exemplary figures. The invention is not limited to the exemplary embodiments. Other features and advantages of various embodiments of the present invention will become apparent by reading the following detailed description with reference to the attached drawings which illustrate the following:

FIG. 1: Shield damping in [dB] for various coatings with the composition according to the invention;

FIG. 2: Shield damping in [dB] for glass fiber reinforced polyester as substrates with the composition (1) according to the invention; and

FIG. 3: Shield damping in [dB] for different temperatures of the composition according to the invention (1) (coating thickness 250 μm).

### DETAILED DESCRIPTION

In an embodiment, the present invention provides improved compositions for shielding against electromagnetic radiation which can be filled with higher solid contents than known from the background art and are compatible with many different fillers. Furthermore, the compositions provided for shielding against electromagnetic radiation are to be characterized by good heat resistance and good aging resistance even at elevated temperatures.

Surprisingly, it has been found that this is achieved by the composition according to the invention and the use thereof as well as the method for its production according to the invention.

The inventive composition accordingly has the following advantages:

Higher filling levels can be achieved by using a polymer matrix that contains at least one polyurethane containing urea groups.

Good heat resistance and good aging resistance can be achieved even at elevated temperatures by using a polymer matrix that contains at least one polyurethane containing urea groups.

It is possible to incorporate ferromagnetic fillers into the composition to cover the low-frequency shielding range.

It is possible to adjust the composition in terms of reflection and absorption by selecting suitable fillers.

It is possible to adjust the composition to different frequency ranges by selecting suitable fillers.

The composition has good adhesion to a plurality of plastics, so that a reliable and economical combination with various plastic housings is possible. Pretreatment may be omitted depending on the type of plastic.

In an embodiment, the present invention provides a composition for shielding against electromagnetic radiation, comprising
a) at least one conductive filler and
b) one polymer matrix that contains at least one polyurethane containing urea groups.

In an embodiment, the present invention provides a composition in the form of a two-component (2K) polyurethane composition. This can be formulated as aqueous or anhydrous.

In an embodiment, the present invention provides a method for producing an inventive composition, comprising the steps of:
a) providing at least one conductive filler, and
b) mixing of at least one conductive filler with the polymers forming the polymer matrix.

In an embodiment, the present invention provides a method for producing a substrate shielded from electromagnetic radiation, comprising or consisting of a composition according to the invention in which such a composition is provided, and
i) the substrate is formed from the composition for shielding electromagnetic radiation, or
ii) the composition for shielding against electromagnetic radiation is incorporated into a substrate, or
iii) a substrate is at least partially coated with the composition for shielding against electromagnetic radiation.

In an embodiment, the present invention provides a use of a composition according to the invention for shielding against electromagnetic radiation.

The present invention is advantageously suited for shielding against electromagnetic radiation over the entire frequency range in which such measures are required to reduce or prevent undesired interference from electromagnetic radiation. The frequency range relevant for EMI shielding is generally in a range from approximately 100 Hz to 100 GHz. The wavelength range which is of particular interest for shielding for automotive applications is from 100 kHz to 100 MHz. The compositions according to the invention are well suited for this purpose. The compositions according to the invention are especially suitable for shielding against low and medium frequencies. For example, a material for absorbing electromagnetic waves having a low frequency, such as a magnetic material, can be used as filler. Furthermore, a material for reflecting electromagnetic waves with a high frequency, e.g. a carbon-rich conductive nanomaterial, can also be used as a filler. Suitable combinations of fillers can be used for broadband application.

Owing to the high compatibility of the polyurethanes containing urea groups used in the composition according to the invention with a multiplicity of different fillers suitable for EMI shielding and the high degree of filling that can be realized, very good shield damping shielding effectiveness (SE) can be achieved. Here, shield damping is made up of proportions SER_{A} for absorption, reflection SER_{R} and multiple reflection SER_{M}. Due to the high flexibility of the composition according to the invention with regard to the type and quantity of the conductive fillers contained and the possibility of using further polymer components, especially conductive polymers, the respectively desired proportion of absorption and reflection in the shield damping can be well controlled. Thus, shielded substrates based on the compositions according to the invention easily fulfil the requirements for electromagnetic compatibility of the material, as defined e.g. in the corresponding CISPR standards (Comité international spécial des perturbations radioélectriques=International Special Committee on Radio Interference). At the same time, substrates which contain or consist of the composition according to the invention for shielding electromagnetic radiation and coatings on this basis are characterized by an overall good application profile. These include their ability to withstand mechanical, thermal or chemical stresses and are characterized for example by good scratch resistance, adhesion, corrosion resistance or elasticity.

The composition according to the invention as defined above and below comprises, as component a), at least one conductive filler.

The electrically conductive filler can advantageously be in the form of particulate materials or fibers. These include powders, nanoparticulate materials, nanotubes, fibers, etc. The fillers can be coated or uncoated or applied to a carrier material.

Preferably, at least one conductive filler is selected from among carbon nanotubes, carbon fibers, graphite, graphene, conductive soot, metal-coated substrates, elemental metals, metal oxides, metal alloys, and mixtures thereof.

Preferred metal-coated substrates include metal-coated carbon fibers, especially nickel-plated carbon fibers and silver-plated carbon fibers. Preferred metal-coated substrates are furthermore silver-coated glass beads.

Suitable elemental metals are selected from cobalt, aluminum, nickel, silver, copper, strontium, iron and mixtures thereof.

Suitable alloys are selected from strontium ferrite, silver copper alloy, silver aluminum alloy, iron nickel alloy, μmetals, amorphous metals (metallic glasses), and mixtures thereof.

In one particular embodiment, the conductive filler comprises at least one ferromagnetic material, preferably selected from iron, cobalt, nickel, oxides and mixed oxides thereof, alloys, and mixtures thereof. These fillers are especially suitable for absorbing electromagnetic waves at a low frequency.

In another particular embodiment, the conductive filler comprises at least one carbon-rich conductive material, preferably selected from carbon nanotubes, carbon fibers, graphite, graphene, conductive soot, and mixtures thereof. These fillers are particularly suitable for reflecting and absorbing electromagnetic waves at a high frequency.

The filler is usually contained in the polymer matrix in a sufficient proportion to achieve the desired electrical conductivity for the intended application. Customary amounts of the conductive filler are, for example, in a range from 0.1 to 95 wt %, based on the total weight of components a) and b). Preferably, the proportion of filler a) is 0.5 to 95 wt %, particularly preferable 1 to 90 wt %, based on the total weight of components a) and b).

The composition according to the invention, as defined above and below, comprises as component b) a polymer matrix containing at least one polyurethane containing urea groups.

The composition according to the invention preferably contains 15 to 99.5 wt %, particularly preferable 20 to 99 wt %, of at least one polyurethane containing urea groups, based on the sum of components a) and b).

In one particular embodiment, the polymer matrix b) consists exclusively of at least one polyurethane containing urea groups.

Polyurethanes containing urea groups contain at least one polymerized amine component which has at least two amine groups that are reactive towards NCO groups.

The proportion of the amine component is preferably 0.01 to 32 mole %, particularly preferable 0.1 to 10 mole %, based on the components used to produce the polyurethane containing urea groups.

In the context of the present invention, polyurethanes containing urea groups are composed of polyisocyanates and thus complementary compounds having at least two groups reactive towards NCO groups.

The reaction of NCO groups with amino groups leads to the formation of urea groups. The reaction of NCO groups with OH groups leads to the formation of urethane groups. Compounds containing only one reactive group per molecule lead to a break in the polymer chain and can be used as regulators. Compounds containing two reactive groups per molecule lead to the formation of linear polyurethanes containing urea groups. Compounds with more than two reactive groups per molecule lead to the formation of branched polyurethanes containing urea groups.

Polyurethane containing urea groups is preferably low-branched or linear. The polyurethane containing urea groups has a linear structure, which is particularly preferable. This means that the polyurethane containing urea groups is composed of diisocyanates and thus complementary divalent compounds.

The degree of branching of polyurethane containing urea groups is preferably 0 to 20%. The degree of branching describes the proportion of nodes in the polymer chain, i.e. the proportion of atoms that are the starting point of at least three polymer chains branching from there. Cross-linking is therefore understood to mean that a branching polymer chain opens into a second branching polymer chain.

Linear polyurethane containing urea groups within the meaning of the invention are polyurethanes containing urea groups which have a degree of branching of 0%.

Low-branched polyurethanes containing urea groups preferably have a degree of branching of 0.01 to 20%, in especially of between 0.01 to 15%.

Groups reactive towards NCO groups preferably have at least one active hydrogen atom.

Suitable complementary compounds are low molecular weight di- and polyols, polymeric polyols, low molecular weight di- and polyamines with primary and/or secondary amino groups, polymeric polyamines, amine-terminated polyoxyalkylene polyols, compounds with at least one hydroxyl group and at least one primary or secondary amino group in the molecule, in particular amino alcohols.

Suitable low molecular weight diols (hereinafter referred to as “diols”) and low molecular weight polyols (hereinafter referred to as “polyols”) have a molecular weight of 60 to less than 500 g/mol. Suitable diols are for example ethylene glycol, propane-1,2-diol, propane-1,3-diol, butane-1,2-diol, butane-1,3-diol, butane-1,4-diol, butane-2,3-diol, pentane-1,2-diol, pentane-1,3-diol, pentane-1,4-diol, pentane-1,5-diol, pentane-2,3-diol, Pentane-2,4-diol, hexane-1,2-diol, hexane-1,3-diol, hexane-1,4-diol, hexane-1,5-diol, hexane-1,6-diol, hexane-2,5-diol, heptane-1,2-diol 1,7-heptanediol, 1,8-octanediol, 1,2-octanediol, 1,9-nonanediol, 1,2-decanediol, 1,10-decanediol, 1,2-dodecanediol, 1,12-dodecanediol, 1,5-hexadiene-3,4-diol, 1,2- and 1,3-cyclopentanediols, 1,2-, 1,3- and 1,4-cyclohexanediols, 1,1-, 1,2-, 1,3- and 1,4-bis(hydroxymethyl)cyclohexanes, 1,1-, 1,2-, 1,3- and 1,4-bis(hydroxy-ethyl)cyclohexanes, Neopentyl glycol, (2)-methyl-2,4-pentanediol, 2,4-dimethyl-2,4-pentanediol, 2-ethyl-1,3-hexanediol, 2,5-dimethyl-2,5-hexanediol, 2,2,4-trimethyl-1,3-pentanediol, pinacol, diethylene glycol, triethylene glycol, dipropylene glycol, tripropylene glycol.

Suitable polyols are compounds with at least three OH groups, e.g. glycerol, trimethylolmethane, trimethylolethane, trimethylolpropane, 1,2,4-butanetriol, tris(hydroxymethyl)amine, tris(hydroxyethyl)amine, tris(hydroxypropyl)amine, pentaerythritol, bis(trimethylolpropane), di(pentaerythritol), di- tri- or oligoglycerols, or sugars, such as glucose, tri- or higher functional polyetherols based on tri- or higher functional alcohols and ethylene oxide, propylene oxide or butylene oxide, or polyesterols. Glycerol, trimethylolethane, trimethylolpropane, 1,2,4-butanetriol, pentaerythritol and their polyetherols based on ethylene oxide or propylene oxide are particularly preferred. Since these compounds lead to branching, they are preferably used in an amount not exceeding 5 wt %, in particular not exceeding 1 wt %, based on the total weight of the compounds complementary to the isocyanates. Specifically, no polyols are used.

Suitable polymeric diols and polymeric polyols preferably have a molecular weight of 500 to 5000 g/mol. The polymeric diols are preferably selected from polyether diols, polyesterdiols, polyether ester diols and polycarbonate diols. The ester group-containing polymeric diols and polyols may have carbonate groups instead of or in addition to carbonic ester groups.

Preferred polyether diols are polyethylene glycols HO(CH₂CH₂O)n-H, polypropylene glycols HO(CH[CH₃]CH₂O)n-H, where n is an integer and n≥4, polyethylene poly-propylene glycols, wherein the sequence of ethylene oxide and propylene oxide units may be blockwise or statistical, polytetramethylene glycols (polytetrahydrofurans), poly-1,3-propanediols or mixtures of two or more of the foregoing compounds. One or else both hydroxyl groups in the above-mentioned diols may be substituted by SH groups.

Preferred polyester diols are those obtained by reacting bivalent alcohols with bivalent carboxylic acids. Instead of the free polycarboxylic acids, the corresponding polycarboxylic acid anhydrides or corresponding polycarboxylic acid esters of lower alcohols or their mixtures can also be used to produce the polyester diols. The polycarboxylic acids can be aliphatic, cycloaliphatic, araliphatic, aromatic or heterocyclic and optionally substituted and/or unsaturated, for example by means of halogen atoms. By way of example, the following are included: Cortic acid, azelaic acid, phthalic acid, isophthalic acid, phthalic anhydride, tetrahydrophthalic anhydride, hexahydrophthalic anhydride, tetrachlorophthalic anhydride, endomethylenetetrahydrophthalic anhydride, glutaric anhydride, maleic acid, maleic anhydride, fumaric acid, dimeric fatty acids. Dicarboxylic acids of the general formula HOOC—(CH₂)_{y}—COOH are preferred, wherein y is a number from 1 to 20, preferably an even number from 2 to 20, e.g. succinic acid, adipic acid, sebacic acid and dodecanedicarboxylic acid.

Polyvalent alcohols include, for example ethylene glycol, propane-1,2-diol, propane-1,3-diol, butane-1,3-diol, butene-1,4-diol, butine-1,4-diol, pentane-1,5-diol, neopentyl glycol, bis-(hydroxymethyl)-cyclohexanes such as 1,4-bis-(hydroxymethyl)cyclohexane, 2-methyl-propane-1,3-diol, methyl pentanediols, further diethylene glycol, triethylene glycol, tetraethylene glycol, polyethylene glycol, dipropylene glycol, polypropylene glycol, dibutylene glycol and polybutylene glycols. Alcohols of the general formula HO—(CH₂)ₓ—OH are preferred, wherein x is a number from 1 to 20, preferably an even number from 2 to 20. By way of example, they include ethylene glycol, butane-1,4-diol, hexane-1,6-diol, octane-1,8-diol and dodecane-1,12-diol. Neopentyl glycol is furthermore preferred.

Suitable polyether diols can be made available by polymerizing ethylene oxide, propylene oxide, butylene oxide, tetrahydrofuran, styrene oxide or epichlorohydrin with itself, e.g. in the presence of BF₃ or by addition of these compounds, optionally in a mixture or successively, of start components with reactive hydrogen atoms, such as alcohols or amines, e.g. water, ethylene glycol, propane-1,2-diol, propane-1,3-diol, 2,2-bis(4-hydroxyphenyl)-propane or aniline. A particularly preferred polyether diol is polytetrahydrofuran. Suitable polytetrahydrofurans can be prepared by cationic polymerization of tetrahydrofuran in the presence of acidic catalysts, such as sulfuric acid or fluorosulfuric acid. Such manufacturing methods are familiar to the POSITA.

Polycarbonate diols are preferred, as they can be obtained, for example, by reacting phosgene with an excess of the low-molecular-weight alcohols mentioned as structural components for the polyester polyols.

Optionally, lactone-based polyester diols can also be used, wherein these are homopolymers or copolymers of lactones, preferably hydroxyl-terminated addition products of lactones to suitable difunctional starter molecules. Lactones are preferably those derived from compounds of the general formula HO—(CH₂)_{z}—COOH, wherein z is a number from 1 to 20 and one H atom of a methylene unit may also be substituted by a C₁ to C₄ alkyl radical. By way of example, they include e-caprolactone, b-propiolactone, g-butyrolactone and/or methyl g-caprolactone and mixtures thereof. Suitable starter components are, e.g., the low-molecular-weight bivalent alcohols mentioned above as structural components for the polyester polyols. The corresponding polymers of e-caprolactone are particularly preferred. Lower polyester diols or polyether diols can also be used as starters for the production of lactone polymers. Instead of the polymerisates of lactones, the corresponding, chemically equivalent polycondensates of the hydroxycarboxylic acids corresponding to the lactones can also be used.

Polycarbonate esters polyether diols and polycarbonate esters polyether polyols are particularly preferred.

Suitable low molecular weight di- and polyamines with primary and/or secondary amino groups have a molecular weight of 32 to less than 500 g/mol. Diamines containing two amino groups selected from the group of primary and secondary amino groups are preferred. Suitable aliphatic and cycloaliphatic diamines include for example ethylenediamine, N-alkyl-ethylenediamine, propylenediamine, 2,2-dimethyl-1,3-propylenediamine, N-alkylpropylenediamine, butylenediamine, N-alkylbutylenediamine, pentanediamine, hexamethylenediamine, N-alkylhexamethylenediamine, heptanediamine, octanediamine, nonanediamine, decanediamine, dodecanediamine, hexadecanediamine, Toluylenediamine, xylylenediamine, diaminodiphenyl-methane, diaminodicyclohexylmethane, phenylenediamine, cyclohexylenediamine, bis(aminomethyl)cyclohexane, diaminodiphenylsulfone, isophoronediamine, 2-butyl-2-ethyl-1,5-pentamethylene diamine, 2,2,4- or 2,4,4-trimethyl-1,6-hexamethylene diamine, 2 aminopropylcyclohexylamine, 3(4)-aminomethyl-1-methylcyclohexylamine, 1,4 diamino-4-methylpentane.

Low molecular weight aromatic di- and polyamines can also be used to produce the compositions according to the invention. Aromatic diamines are preferably selected from bis-(4-amino-phenyl)-methane, 3-methylbenzidine, 2,2-bis-(4-aminophenyl)-propane, 1,1-bis-(4-aminophenyl)-cyclohexane, 1,2-diaminobenzene, 1,4-diaminobenzene, 1,4-diaminonaphthalene, 1,5-diaminonaphthalene, 1,3-diaminotoluene, m-xylylenediamine, N,N′-dimethyl-4,4′-biphenyl-diamine, bis-(4-methyl-aminophenyl)-methane, 2,2-bis-(4-methylaminophenyl)-propane or mixtures thereof.

The low-molecular-weight di- and polyamines used to prepare the compositions according to the invention preferably have a proportion of aromatic di- and polyamines on all di- and polyamines of at most 50 mol %, particularly preferably of at most 30 mol %, especially of at most 10 mol %. In a particular embodiment, the low-molecular di- and polyamines used to produce the compositions according to the invention do not contain any aromatic di- and polyamines. In a further particular embodiment for producing two-component (2K) polyurethanes according to the invention, aromatic di- and polyamines are used. The proportion of aromatic di- and polyamines in all di- and polyamines is then at most 50 mol %, preferably at most 30 mol %, especially at most 10 mol %.

Suitable polymeric polyamines preferably have a molecular weight of 500 to 5000 g/mol. These include polyethyleneimines and amine-terminated polyoxy-alkylene polyols, such as a,w-diaminopolyethers, which can be produced by aminating polyalkylene oxides with ammonia. Special amine-terminated polyoxyalkylene polyols are so-called jeffamines or amine-terminated polytetramethylene glycols.

Suitable compounds having at least one hydroxyl group and at least one primary or secondary amino group in the molecule include dialkanolamines, such as diethanolamine, dipropanolamine, diisopropanol-amine, 2-amino-1,3-propanediol, 3-amino-1,2-propanediol, 2-amino-1,3-propanediol, dibu-tanolamine, diisobutanolamine, bis(2-hydroxy-1-butyl)amine, bis(2-hydroxy-1-propyl)amine and dicyclohexanolamine.

Of course, it is also possible to use mixtures of the above-mentioned amines.

According to the invention, the polyurethane containing urea groups contains at least one amine component containing amine groups as a copolymerized component, which has at least two amine groups reactive towards NCO groups. This leads to the formation of urea groups during the polyaddition.

In a preferred embodiment, the polyurethane containing urea groups contains at least one diamine component copolymerized with it.

The polymerized diamond component is preferably selected from ethylenediamine, 1,3-propylenediamine, 1,4-tetramethylenediamine, 1,5-pentamethyldiamine, 1,6-hexamethylenediamine, 2-methylpentamethylenediamine, 1,7-heptamethylenediamine, 1,8-octamethylenediamine, 1,9-nonamethylenediamine, 1,10-diaminododecane, 1,12-diaminoododecane, 2,2,4-trimethylhexamethylenediamine, 2,4,4-trimethylhexa-methylenediamine, 2,3,3-trimethylhexamethylenediamine, 1,6-diamino-2,2,4-trimethylhexane, 1-amino-3-aminomethyl-3, 5,5-trimethylcyclohexane, 1,4-cyclohexylenediamine, bis-(4-aminocyclohexyl)-methane, isophoronediamine, 1-methyl-2,4-diaminocyclohexanes and mixtures thereof.

Isocyanates are N substituted organic derivatives (R N═C═O) of isocyanic acid (HNCO). Organic isocyanates are compounds in which the isocyanate group (—N═C═O) is bonded to an organic residue. Polyfunctional isocyanates are compounds having two or more (e.g. 3, 4, 5, etc.) isocyanate groups in the molecule.

The polyisocyanate is generally selected from di- and polyfunctional isocyanates, the allophanates, isocyanurates, uretdiones or carbodiimides of difunctional isocyanates and mixtures thereof. The polyisocyanate preferably contains at least one difunctional isocyanate. In particular, difunctional isocyanates (diisocyanates) are used.

Suitable polyisocyanates are generally all aliphatic and aromatic isocyanates, provided that they have at least two reactive isocyanate groups. In the context of the invention, the term aliphatic diisocyanates also comprises cycloaliphatic (alicyclic) diisocyanates.

In a preferred embodiment, the polyurethane containing urea groups contains aliphatic polyisocyanates incorporated, wherein the aliphatic polyisocyanate may be replaced by up to 80 wt %, preferably up to 60 wt %, based on the total weight of the polyisocyanates, by at least one aromatic polyisocyanate. In one particular embodiment, the polyurethane containing urea groups contains only aliphatic polyisocyanates incorporated.

The polyisocyanate component preferably has an average content of 2 to 4 NCO groups. Diisocyanates, i.e. esters of isocyanic acid having the general structure O═C═N—R′—N═C═O, wherein R′ is an aliphatic or aromatic radical, are preferred.

Suitable polyisocyanates are selected from compounds with 2 to 5 isocyanate groups, isocyanate prepolymers with an average number of 2 to 5 isocyanate groups and mixtures thereof. These include aliphatic, cycloaliphatic and aromatic di, tri and higher polyisocyanates.

The polyurethane containing urea groups preferably contains at least one aliphatic polyisocyanate incorporated therein. Suitable aliphatic polyisocyanates are selected from ethylene diisocyanate, propylene diisocyanate, tetramethylene diisocyanate, pentamethylene diisocyanate, hexamethylene diisocyanate (HDI), 1,12-diisocyanatododecane, 4-isocyanatomethyl-1,8-octamethylene diisocyanate, triphenylmethane-4,4′,4′,4″-triisocyanate, 1,6-diisocyanato-2,2,4-trimethylhexane, 1,6-diisocyanato-2,4,4,4-trimethylhexane, isophorone diisocyanate (=3-isocyanate-methyl-3,5,5-trimethylcyclohexylisocyanate, 1-isocyanato-3-isocyanatomethyl-3,5,5-trimethylcyclohexane, IPDI), 2,3,3-trimethylhexamethylene diisocyanate, 1,4-cyclohexylene diisocyanate, 1-methyl-2,4-diisocyanatocyclohexane, dicyclohexylmethane-4,4′-diisocyanate (=methylene bis(4-cyclohexylisocyanate)).

The aromatic polyisocyanate is preferably selected from 1,3-phenylene diisocyanate, 1,4-phenylene diisocyanate, 2,4- and 2,6-toluene diisocyanate and mixtures of isomers thereof, 1,5-naphthylene diisocyanate, 2,4′- and 4,4′-diphenylmethane diisocyanate, hydrogenated 4,4′-diphenylmethane diisocyanate (H12MDI), xylylene diisocyanate (XDI), tetramethylxylene diisocyanate (TMXDI), 4,4′-dibenzyl diisocyanate, 4,4′-diphenyldimethyl methane diisocyanate, di- and tetraalkyldiphenylmethane diisocyanates, ortho-tolydine diisocyanate (TODI) and mixtures thereof.

In a suitable embodiment, the polyurethane containing urea groups contains at least one polyisocyanate with a uretdione, isocyanurate, urethane, allophanate, biuret, iminooxadiazinedione and/or oxadiazinedione structure.

In a preferred embodiment, the polyurethane containing urea groups contains at least one aliphatic polyisocyanate with a uretdione, isocyanurate, urethane, allophanate, biuret, iminooxadiazine dione and/or oxadiazine trione structure.

In a further preferred embodiment, the polyurethane containing urea groups contains at least one aliphatic polyisocyanate and additionally at least one polyisocyanate based on these aliphatic polyisocyanates and having a uretdione, isocyanurate, urethane, allophanate, biuret, iminooxadiazinedione and/or oxadiazinedione structure.

These are preferably polyisocyanates or polyisocyanate mixtures with exclusively aliphatically and/or cycloaliphatically bound isocyanate groups and an average NCO functionality of 2 to 4, preferably 2 to 2.6 and particularly preferably 2 to 2.4.

The polyurethane containing urea groups contains at least one aliphatic diisocyanate, which is selected from hexamethylene diisocyanate, isophorone diisocyanate and mixtures thereof.

In a preferred embodiment, the polyurethane containing urea groups is composed of aliphatic polyisocyanates and thus complementary aliphatic compounds having at least two groups reactive towards NCO groups, wherein the aliphatic polyisocyanate may be replaced by up to 50 wt %, based on the total weight of the polyisocyanates, by at least one aromatic polyisocyanate.

In a particularly preferred embodiment, the polyurethane containing urea groups is composed of aliphatic polyisocyanates and thus complementary aliphatic compounds having at least two groups reactive towards NCO groups, wherein the aliphatic polyisocyanate may be replaced by up to 30 wt %, based on the total weight of the polyisocyanates, by at least one aromatic polyisocyanate.

In one particular embodiment, the polyurethane containing urea groups is composed of aliphatic polyisocyanates and thus complementary aliphatic compounds having at least two groups reactive towards NCO groups.

In one particular embodiment, a diamine-modified polycarbonate ester-polyether polyurethane is used as a polyurethane containing urea groups.

In a preferred embodiment, the polymer matrix b) additionally contains at least one conductive polymer which is different from the polyurethane containing urea groups.

Suitable conductive polymers generally have a conductivity of at least 1×10³ S m⁻¹ at 25° C., preferably at least 2×10³ S m⁻¹ at 25° C.

Suitable conductive polymers are selected from polyanilines, polypyrroles, polythiophenes, polyethylene dioxythiophenes (PEDOT), poly(p-phenylene-vinylenes), polyacetylenes, polydiacetylenes, polyphenylene sulfides (PPS), polyperinaphthalenes (PPN), polyphthalocyanines (PPhc), sulfonated polystyrene polymers, carbon fiber-filled polymers and mixtures, derivatives and copolymers thereof.

The proportion by weight of the at least conductive polymer is preferably 0 to 10 wt %, such as 0.1 to 5 wt %, based on the total weight of component b).

In one possible embodiment, the polymer matrix b) additionally contains at least one non-conductive matrix polymer which is different from the polyurethane containing urea groups.

Suitable non-conductive matrix polymers, which are different from the polyurethane containing urea groups, are preferably selected from polyurethanes, silicones, fluorosilicones, polycarbonates, ethylene vinyl acetates (EVA), acrylonitrile butadiene rubbers (ABN), acrylonitrile butadiene styrenes (ABS), Acrylonitrile-methyl methacrylates (AMMA), acrylonitrile-styrene acrylates (ASA), cellulose acetates (CA), cellulose acetate butyrates (CAB), polysulfones (PSU), poly(meth)acrylates, polyvinyl chlorides (PVC), polyphenylene ethers (PPE=polyphenylene oxides (PPO)), polystyrenes (PS), polyamides (PA), polyolefins, z. e.g. polyethylene (PE) or polypropylene (PP), polyketones (PK), e.g. aliphatic polyketones or aromatic polyketones, polyetherketones (PEK), e.g. aliphatic polyetherketones or aromatic polyetherketones, polyimides (PI), polyetherimides, polyethylene terephthalates (PET), polybutylene terephthalates (PBT), fluoropolymers, polyesters, polyacetals, e.g. polyoxymethylene (POM), liquid crystal polymers, polyethersulfones (PES), epoxy resins (EP), phenolic resins, chlorosulfonates, polybutadienes, polybutylene, polyneoprenes, polynitriles, polyisoprenes, natural rubbers Copolymer rubbers such as styrene-isoprene-styrenes (SIS), styrene-butadiene-styrenes (SBS), ethylene-propylenes (EPR), ethylene-propylene-diene rubbers (EPDM), styrene-butadiene rubbers (SBR) and copolymers and blends thereof.

Preferred aliphatic and aromatic polyetherketones are aliphatic polyetheretherketones or aromatic polyetheretherketones (PEEK). A particular embodiment is aromatic polyetheretherketones.

The proportion by weight of the at least one non-conductive matrix polymer other than the polyurethane containing urea groups is preferably 0 to 20 wt %, preferably 0 to 15 wt %, based on the total weight of component b). If such a non-conductive matrix polymer is present, it is present in an amount of at least 0.1, preferably at least 0.5 wt %, based on the total weight of component b).

The conductive polymer and the non-conductive polymer can be mixed into a blend of components using standard techniques such as melt blending or dispersing the filler particles during polymerization of the matrix polymer (sol-gel method). Homogeneous and heterogeneous blends are possible. No macrophases are present in a homogeneous blend, whereas macrophases are present in a heterogeneous blend.

In a preferred embodiment, the inventive composition contains
a) 0.5 to 95 wt % of at least one conductive filler,
b1) 15 to 99.5 wt % of at least one polyurethane containing urea groups,
b2) 0 to 20 wt % of at least one non-conductive matrix polymer different from b1),
b3) 0 to 10 wt % of at least one conductive polymer,
c) optionally at least one additive, wherein each additive is present in an amount of 0 to 3 wt %, optionally water, added to 100 wt %.

Suitable additives c) are selected from antioxidants, heat stabilizers, flame retardants, light stabilizers (UV stabilizers, UV absorbers or UV blockers), catalysts for the cross-linking reaction, thickeners, thixotropic agents, surface active agents, viscosity modifiers, lubricants, dyes, nucleating agents, antistatics, mold release agents, defoamers, bactericides, etc.

Nonionic surfactants can be used as surface-active agents. A preferred embodiment is alkoxylated alcohols. Preferred alkoxylated alcohols are ethoxylated alcohols having preferably 6 to 20 carbon atoms in the alkyl radical and on average 1 to 150 moles, preferably 2 to 100 moles, in particular 2 to 50 mole, of ethylene oxide (EO) per mole of alcohol. The alcohol radical may be linear or branched, preferably linear. Preferably branched alcohol radicals are methyl-branched radicals in the 2-position, as they are usually present in oxo-alcohol radicals.

The ethoxylated alcohols are preferably selected from:
C₁₂C₁₄ alcohols having 2 to 150 EO,
C₉C₁₁ alcohols having 2 to 150 EO,
C₁₃ oxo-alcohols having 2 to 150 EO,
C₁₃ C₁₅ alcohols having 2 to 150 EO,
C₁₂C₁₈ alcohols having 2 to 150 EO,
   and mixtures of two or more than two of the aforementioned ethoxylated alcohols.

In one particular embodiment, the ethoxylated alcohol is a C₁₃ oxo-alcohol having 2 to 50 moles of EO, especially 2 to 15 moles of EO per mole of alcohol.

The degrees of ethoxylation recited represent statistical mean values (number average, Mn) which may be an integer or a fractional number for a particular product. Other suitable surface-active agents are fatty alcohols having 1 to 150 EO, preferably 2 to 100 moles, ethylene oxide (EO) per mole of alcohol. Other suitable surface-active agents are also alkoxylated alcohols containing ethylene oxide (EO) and at least one further alkylene oxide incorporated therein. These include propylene oxide (PO) and butylene oxide (BO). Block copolymers with EO and PO block units are preferably used.

Polyetherols can also be used as surface-active agents. Suitable polyetherols may be linear or branched, preferably linear. Suitable polyetherols generally have a number average molecular weight in the range of approximately 200 to 100000, preferably 300 to 50000. Suitable polyetherols include polyalkylene glycols such as polyethylene glycols, polypropylene glycols, polytetrahydrofurans and alkylene oxide copolymers. Suitable alkylene oxides for producing alkylene oxide copolymers include for example ethylene oxide, propylene oxide, 1,2- and 2,3-butylene oxide. Suitable examples include copolymers of ethylene oxide and propylene oxide, copolymers of ethylene oxide and butylene oxide and copolymers of ethylene oxide, propylene oxide and at least one butylene oxide. One suitable embodiment is polytetrahydrofuran homo- and copolymers. The alkylene oxide copolymers can contain the alkylene oxide units randomly distributed or in the form of blocks polymerized into the polymer. Ethylene oxide homopolymers and ethylene oxide/propylene oxide copolymers are suitable.

In addition, the composition may contain, as component d) at least one filling and reinforcing material different from components a) to c).

The term “filler and reinforcing material” (=component d)) is broadly understood within the scope of the invention and comprises particulate fillers, fibrous materials and any desired transition forms. Particulate fillers can have a wide range of particle sizes, from powdery to coarse-grained particles. Organic or inorganic fillers and reinforcing substances can be used as filling material. For example, inorganic fillers such as carbon fibers, kaolin, chalk, wollastonite, talc, calcium carbonate, silicates, titanium dioxide, zinc oxide, glass particles, e.g. glass beads, nanoscale layered silicates, nanoscale aluminum oxide (Al₂O₃), nanoscale titanium dioxide (TiO₂), layered silicates and nanoscale silicon dioxide (SiO₂) can be used. The fillers may also be surface treated.

Suitable phyllosilicates include kaolin, serpentine, talc, mica, vermiculite, illite, smectite, montmorillonite, hectorite, double hydroxides and mixtures thereof. The phyllosilicates can be surface-treated or untreated.

Furthermore, one or more fibrous materials can be used. These are preferably selected from known inorganic reinforcement fibers, such as boron fibers, glass fibers, silica fibers, ceramic fibers and basalt fibers; organic reinforcement fibers, such as aramid fibers, polyester fibers, nylon fibers and polyethylene fibers; and natural fibers, such as wood fibers, flax fibers, hemp fibers and sisal fibers.

The component d) is preferably used, if present, in an amount of 1 to 80 wt %, based on the total amount of components a) to d).

As a further embodiment, the inventive composition can be in the form of foam. Foam within the meaning of the invention is a porous, at least partially open-cell structure with cells communicating with one another.

To produce a polyurethane foam, the components of the composition according to the invention can be mixed, foamed and cured, optionally after prepolymerization of at least part thereof. Curing is preferably done by chemical cross-linking. In principle, foaming can be achieved by the carbon dioxide formed by the reaction of the isocyanate groups with water, but the use of other foaming agents is also possible. In principle, blowing agents from the hydrocarbon class such as C3-C6 alkanes, e.g. n-butane, sec-butane, isobutane, n-pentane, isopentane, cyclopentane, hexanes, etc. or halogenated hydrocarbons such as dichloromethane, dichloromonofluoromethane, chlorodifluoroethanes, 1,1-dichloro-2,2,2-trifluoroethane, 2,2-dichloro-2-fluoroethane, in particular chlorine-free fluorocarbons such as difluoromethane, trifluoromethane, difluoroethane, 1,1,1,2-tetrafluoroethane, 1,1,2,2-tetrafluoroethane, 1,1,1,3,3-pentafluoropropane, 1,1,1,3,3,3-hexafluoropropane, 1,1,1,3,3-pentafluorobutane, heptafluoropropane or sulphur hexafluoride. Mixtures of these blowing agents are also possible. Subsequent curing is typically done at a temperature of approximately 10 to 80° C., especially 15 to 60° C., especially at room temperature. After curing, any residual moisture that is still present can be removed, if necessary, using conventional methods, e.g. convective air drying or microwave drying.

In a further preferred embodiment, the composition according to the invention is in the form of a two-component (2K) polyurethane composition. Suitable two-component polyurethane coatings comprise e.g. a component (I) and a component (II), wherein component (I) contains at least one of the aforementioned compounds having at least two groups reactive towards NCO groups, such as are used for producing the polyurethanes containing urea groups. Alternatively or additionally, component (I) may comprise a prepolymer containing at least two groups reactive towards NCO groups. Component (II) contains at least one of the aforementioned polyisocyanates as used in the production of polyurethanes containing urea groups. Alternatively or additionally, component (II) may comprise a prepolymer containing at least two NCO groups. Optionally, components (I) and/or (II) may comprise further oligomeric and/or polymeric constituents. For example, in the case of an aqueous two-component (2K) polyurethane composition, component (I) may comprise one or more further polyurethane resins and/or acrylate polymers and/or acrylated polyesters and/or acrylated polyurethanes. Further polymers are usually water-soluble or water-dispersible and have hydroxyl groups and possibly acid groups or salts thereof. The other previously mentioned components of the composition according to the invention may each be present only in component (I) or (II) or proportionately in both.

The two components (I) and (II) of the two-component (2K) polyurethane composition according to the invention are prepared from the individual constituents by the usual methods with stirring. The coating compositions from these two components (I) and (II) are also produced by stirring or dispersing using the devices customarily used, e.g. by means of dissolvers or the like, or by means of 2-component dosing and mixing systems which are also customarily used.

The two-component (2K) polyurethane composition may be in the form of an aqueous coating. In the ready-to-use state, a suitable aqueous two-component (2K) polyurethane coating generally comprises, based on the total weight of the composition:
0.5 to 95 wt % of at least one conductive filler (previously defined as component a)),
15 to 99.5 wt % of at least one polyurethane containing urea groups (previously defined as component b1))
0 to 20 wt % of at least one non-conductive matrix polymer different from b1) (previously defined as component b2)),
0 to 7 wt % of at least one conductive polymer (previously defined as component b3)),
10 to 90 wt %, preferably 20 to 80 wt % of water,
0 to 50 wt %, preferably 0 to 20 wt % of organic solvents,
Further additives, fillers and reinforcing materials are 100 wt %.

With a two-component (2K) polyurethane composition according to the invention, plastics such as ABS, AMMA, ASA, CA, CAB, EP, UF, CF, MF, MPF, PF, PAN, PA, PC, PE, HDPE, LDPE, LLDPE, UHMWPE, PET, PMMA, PP, PS, SB, PUR, PVC, RF, SAN, PBT, PPE, POM, PUR-RIM, SMC, BMC, PP-EPDM and UP (short designations according to DIN 7728T1) can be coated. The plastics to be coated can of course also be polymer blends, modified plastics or fiber-reinforced plastics. Furthermore, the two-component (2K) polyurethane composition according to the invention can also be applied to other substrates, for example metal, wood or paper or mineral substrates.

In the case of non-functionalized and/or non-polar substrate surfaces, these can be subjected to a pretreatment, such as with plasma or flame, before coating.

If desired, the substrates may be primed prior to coating with the two-component (2K) polyurethane composition of the present invention. All common primers can be used, both conventional and aqueous primers. Of course, radiation-curable, such as thermally curable or dual cure primers can be used.

Application is applied by common methods such as spraying, scraping, dipping, brushing or by means of coil coating.

The coating agents according to the invention are usually cured at temperatures not exceeding 120° C., preferably at temperatures not exceeding 100° C. and especially preferably at a maximum of 80° C.

Another subject matter of the invention is a method for producing a composition for shielding against electromagnetic radiation, comprising the steps of:
a) providing at least one conductive filler, and
b) mixing of at least one conductive filler with the polymers forming the polymer matrix.

A further subject matter of the invention is a method for producing a substrate shielded from electromagnetic radiation comprising or consisting of a composition for shielding electromagnetic radiation, as previously defined, in which such a composition for shielding against electromagnetic radiation is provided, and
i) the substrate is formed (molds) from the composition for shielding against electromagnetic radiation; or
ii) incorporates (incorporation) the composition for shielding electromagnetic radiation into a substrate; or
iii) a substrate is at least partially coated (coating) with the electromagnetic radiation shielding composition.

Within the scope of the invention, substrate is understood to mean any sheet-like structure onto which the composition according to the invention can be applied or into which the composition according to the invention can be incorporated or which consists of the composition according to the invention. Sheet-like structures include, for example, housings, cable sheaths, shells, covers, sensor systems.

In variant i), the material composition of the substrate corresponds to the composition according to the invention for shielding against electromagnetic radiation. The substrate is formed by applying at least one molding step to the latter. In variants ii) and iii), in addition to the composition according to the invention, a different substrate is used for shielding against electromagnetic radiation.

In variants ii) and iii), the substrate is preferably selected from plastics, metals, wood materials, glass, ceramics, mineral materials, textile materials, paper materials and composites of at least two of the aforementioned components.

Suitable substrates for variants ii) and iii) include plastics, polymer blends, modified plastics or fiber-reinforced plastics, metals, wood, paper or mineral substrates. In one particular embodiment of variant iii), the substrate is a composite comprising at least one reinforced and/or filled plastic material or consisting of at least one reinforced and/or filled plastic material. Suitable fillers and reinforcing substances are those previously mentioned as component d), which is referred to here.

Suitable plastics in variants ii) and iii) can, in principle, be selected from those plastics which are also used as matrix polymers and for coating with a two-component (2K) polyurethane composition according to the invention. This disclosure is referred to here.

The plastics selected are preferably polyurethanes, silicones, fluorosilicones, polycarbonates, ethylene-vinyl acetates (EVA), acrylonitrile-butadiene rubbers (ABN), acrylonitrile-butadiene-styrenes (ABS), acrylonitrile-methyl methacrylates (AMMA), Acrylonitrile styrene acrylates (ASA), cellulose acetates (CA), cellulose acetate butyrates (CAB), polysulfones (PSU), poly(meth)acrylates, polyvinyl chlorides (PVC), polyphenylene ethers (PPE=polyphenylene oxides (PPO)), polystyrenes (PS), polyamides (PA), polyolefins, e.g. e.g. polyethylene (PE) or polypropylene (PP), polyketones (PK), e.g. aliphatic polyketones or aromatic polyketones, polyetherketones (PEK), e.g. aliphatic polyetherketones or aromatic polyetherketones, polyimides (PI), polyetherimides, polyethylene terephthalates (PET), polybutylene terephthalates (PBT), fluoropolymers, polyesters, polyacetals, e.g. polyoxymethylene (POM), liquid crystal polymers, polyethersulfones (PES), epoxy resins (EP), phenolic resins, chlorosulfonates, polybutadienes, polybutylenes, polyneoprenes, polynitriles, polyisoprenes, natural rubbers, copolymer rubbers such as styrene-isoprene-styrenes (SIS), Styrene-butadiene-styrenes (SBS), ethylene-propylenes (EPR), ethylene-propylene-diene rubbers (EPDM), nitrile-butadiene rubbers (NBR), styrene-butadiene rubbers (SBR) and copolymers and blends thereof.

Preferred aliphatic and aromatic polyetherketones are aliphatic polyetheretherketones or aromatic polyetheretherketones (PEEK). A particular embodiment is aromatic polyetheretherketones.

In one embodiment, the substrate comprises at least one polymer or the substrate consists of at least one polymer selected from so-called high-performance plastics, which are characterized by their temperature resistance, but also chemical resistance and good mechanical properties. Such polymers are particularly suitable for applications in the automotive sector. The polymers are then preferably selected from aliphatic and aromatic polyketones, aliphatic and aromatic polyether ketones (PEK), especially aliphatic and aromatic polyether ether ketones (PEEK), high temperature polyamides (HTPA), polyamide imides (PAI), polyphenylene sulfides (PPS), polyarylsulfones and mixtures (blends) thereof.

The substrate specifically comprises at least one polymer or consists of at least one polymer selected from aliphatic and aromatic polyketones (PK), aliphatic and aromatic polyether ether ketones (PEEK), polyamides (PA), in particular high-temperature polyamides (HTPA), polycarbonates (PC), polybutylene terephthalate (PBT) and mixtures (blends) thereof.

In another preferred embodiment, the polyarylsulfones are selected from polysulfones (psu), polyether sulfones (PES), polyphenylene sulfones (PPSU), and bends of PSU and ABS.

A preferred embodiment comprises a method as defined above followed by an additional drying and/or curing step.

In order to be used in the method according to the invention, at least one additive other than the conductive filler a) can be added to the composition for shielding electromagnetic radiation. Suitable additives are those mentioned above.
Molding (=variant 1)

In a first variant of the method according to the invention, the substrate is formed from the composition for shielding against electromagnetic radiation. The inventive composition is plasticized and undergoes a molding step. These are molding steps that are familiar to the POSITA, such as casting molds, blow molds, calendering, injection molding, pressing, injection stamping, embossing, extruding, etc.
Incorporation (=Variant 2)

In a second variant of the method according to the invention, the composition for shielding against electromagnetic radiation is incorporated into a substrate.

In principle, suitable incorporation methods are familiar to the POSITA and comprise those normally used for compounding plastic molding compounds.

Incorporation can be done either in the melt or in the solid phase. A combination of these methods is also possible, for example by premixing in the solid phase and subsequent mixing in the melt. Conventional devices, such as kneaders or extruders, can be used.

The composition obtained by incorporating the electromagnetic radiation shielding composition into the substrate may be subjected to at least one further process step. This is preferably selected from molding, drying, curing or a combination thereof.
Coating (=Variant 3)

In a third variant of the method according to the invention, a substrate is at least partially coated with the composition for shielding against electromagnetic radiation.

The substrates are coated with the compositions described above for shielding against electromagnetic radiation using conventional methods that are familiar to the POSITA. To this end, the composition for shielding against electromagnetic radiation or a coating compound containing it is applied to the substrate to be coated in the desired thickness and optionally dried and/or optionally partially or completely cured. This process can be repeated one or more times if desired. The application can be applied to the substrate in a known manner, e.g. by dipping, spraying, filling, squeegee, brushing, rolling, dip coating, rolling, casting, laminating, back injection, in-mould coating or co-extrusion, screen printing, pad printing, spinning.

The coating can be applied one or more times, for example, by a spraying method, such as air pressure, airless or electrostatic spraying methods.

The coating thickness is generally in a range from approximately 5 to 1000 μm, preferably from 10 to 500 μm.

The application and optionally drying and/or curing of the coatings can be applied under normal temperature conditions, i.e. without heating the coating, but also at elevated temperature. The coating can be dried and/or cured, for example, during and/or after application at elevated temperature, for example at 25 to 200° C., preferably 30 to 100° C.

A further subject matter of the invention is the use of the composition as defined above for shielding electromagnetic radiation. In particular, the composition according to the invention, as defined above, can be used to shield electromagnetic radiation in electronic housings. Electronic housings are housings for e-mobility vehicles, especially for power electronics, battery and electric motor.

By way of example, the following serve to illustrate the invention without limiting it in any way.

### EXAMPLE

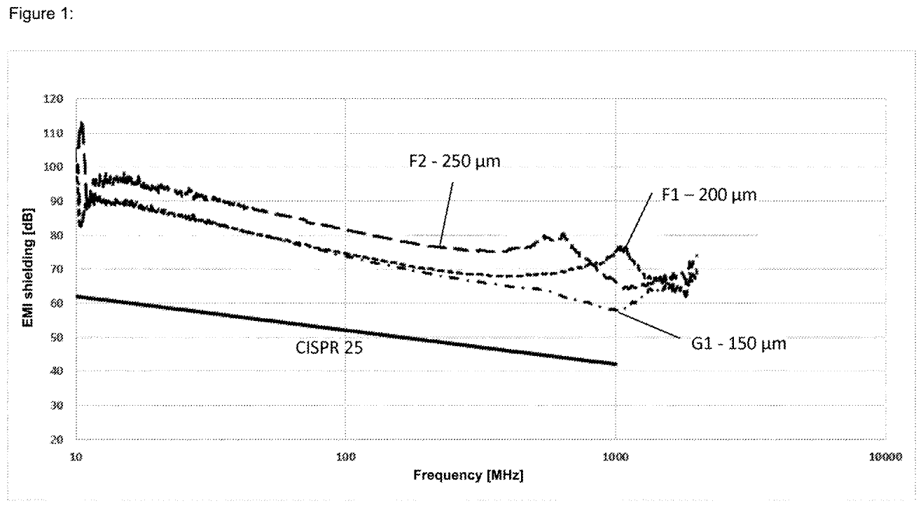

FIG. 1: Shield damping in [dB] for various coatings with the composition according to the invention:

Sample F1: Coating thickness 200 μm,

Sample F2: Coating thickness 250 μm,

Sample G1: Coating thickness 150 μm.

Shield damping is measured according to ASTM D 4935-99. The composition (1) comprises:
56 wt % a polyurethane urea, based on polycarbonate ester polyether diol,
0.8 wt % of poly(3,4-ethylenedioxythiophene) polystyrene sulfonate as conductive polymer,
41.8 wt % of metal filler,
1.4 wt % of conductive soot.

The composition (2) contains:
43.8 wt % of a polyurethane urea, based on polycarbonate ester polyether diol,
0.1 wt % of carbon nanotubes,
52.9 wt % of metal filler,
1.9 wt % of conductive soot,
0.7 wt % of protection against ageing (Tinuvin® B75: mixture of Irganox® 1135 (CAS 125643-61-0 sterically hindered phenol), Tinuvin® 765 (bis(1,2,2,6,6-pentamethyl-4-piperidyl)sebacate and 1-(methyl)-8-(1,2,2,6,6-pentamethyl-4-piperidyl) sebacate, CAS No: 41556-26-7 and 82919-37-7), and Tinuvin® 571 (mixture of 2-(2H-benzotriazol-2-yl)-4-methyl-(n)-dodecylphenol, 2-(2H-benzotriazole-2-yl)-4-methyl-(n)-tetracosylphenol and 2-(2H-benzotriazole-2-yl)-4-methyl-5,6-didodecylphenol CAS No. 125304-04-3/23328-53-2/104487-30-1).

The composition (3) contains:
56 wt % of polyurethane urea based on poly THF (MW 2000),
0.8 wt % of poly(3,4-ethylenedioxythiophene) polystyrene sulfonate as conductive polymer,
41.8 wt % of metal filler,
1.4 wt % of conductive soot.

The composition (4) contains:
56 wt % of polyurethane urea based on polycaprolactone (MW 1000),
0.8 wt % of poly(3,4-ethylenedioxythiophene) polystyrene sulfonate as conductive polymer,
41.8 wt % of metal filler,
1.4 wt % of conductive soot.

The resulting composition (1) was applied to a polymer surface (polyamide 66) of different layer thickness:

Sample F1: Coating thickness 200 μm,

Sample F2: Coating thickness 250 μm,

Sample G1: Coating thickness 150 μm,

This was followed by the measurement for shield damping. The shielding values of the coatings are all well above the CISPR 25 requirements (see FIG. 1).

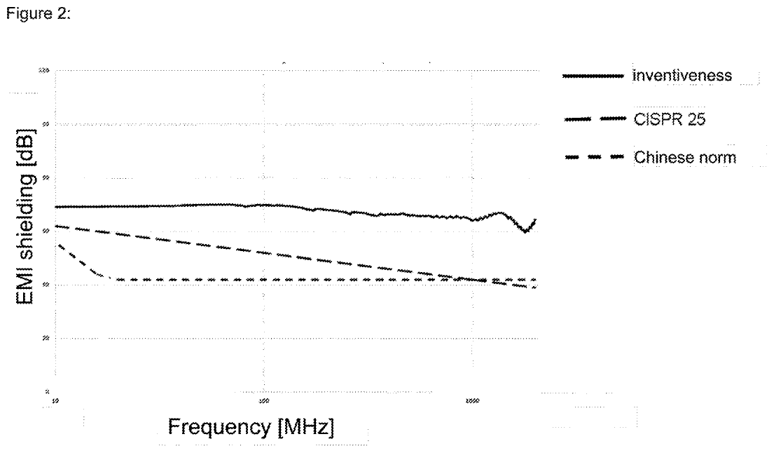

FIG. 2: Shield damping in [dB] for glass fiber reinforced polyester as substrates with the composition (1) according to the invention.

The obtained composition (1) was applied to a polymer surface (glass fiber reinforced polyester) with a layer thickness of 250 μm:

This was followed by the measurement for shield damping. The shielding values of the coating are all far above the CISPR 25 requirements and the Chinese shielding norm (see FIG. 2).

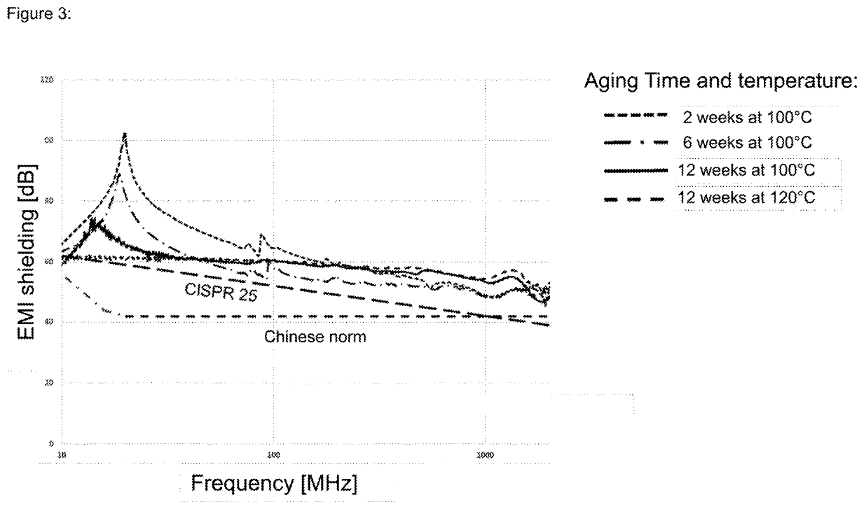

FIG. 3: Shield damping in [dB] for different temperatures of the composition according to the invention (1) (coating thickness 250 μm).

The obtained composition (1) was applied to a thermally and electrically conductive thermoplastic (graphite-filled polyamide 66) with a layer thickness of 250 μm:

This was followed by the measurement for shield damping. The shielding values of the coatings all far exceed the CISPR 25 requirements and the Chinese shielding norm (see FIG. 3). The peaks between approx. 12 MHz and 35 MHz are measurement related and due to a resonance phenomenon in the measuring apparatus.

While the invention has been illustrated and described in detail in the drawings and foregoing description, such illustration and description are to be considered illustrative or exemplary and not restrictive. It will be understood that changes and modifications may be made by those of ordinary skill within the scope of the following claims. In particular, the present invention covers further embodiments with any combination of features from different embodiments described above and below. Additionally, statements made herein characterizing the invention refer to an embodiment of the invention and not necessarily all embodiments.

The terms used in the claims should be construed to have the broadest reasonable interpretation consistent with the foregoing description. For example, the use of the article “a” or “the” in introducing an element should not be interpreted as being exclusive of a plurality of elements. Likewise, the recitation of “or” should be interpreted as being inclusive, such that the recitation of “A or B” is not exclusive of “A and B,” unless it is clear from the context or the foregoing description that only one of A and B is intended. Further, the recitation of “at least one of A, B and C” should be interpreted as one or more of a group of elements consisting of A, B and C, and should not be interpreted as requiring at least one of each of the listed elements A, B and C, regardless of whether A, B and C are related as categories or otherwise. Moreover, the recitation of “A, B and/or C” or “at least one of A, B or C” should be interpreted as including any singular entity from the listed elements, e.g., A, any subset from the listed elements, e.g., A and B, or the entire list of elements A, B and C.

1.-16. (canceled)

17: A composition for shielding against electromagnetic radiation, comprising:
a) at least one conductive filler; and
b) a polymer matrix comprising at least one polyurethane containing urea group,
wherein the at least one polyurethane containing urea group has a degree of branching from 0 to 20%.

18: A composition for shielding against electromagnetic radiation, comprising:
a) at least one conductive filler; and
b) a polymer matrix consisting of at least one polyurethane containing urea group,
or
a) at least one conductive filler; and
b) a polymer matrix containing at least one polyurethane containing urea group and additionally at least one conductive polymer.

19: The composition according to claim 17, wherein the polymer matrix comprises at least one non-conductive matrix polymer which is different from the at least one polyurethane containing urea group, selected from polyurethanes, silicones, fluorosilicones, polycarbonates, ethylene vinyl acetates, acrylonitrile butadiene rubbers, acrylonitrile butadiene styrenes, acrylonitrile methyl methacrylates, acrylonitrile styrene acrylates, cellulose acetates, cellulose acetate butyrates, polysulfones, poly(meth)acrylates, polyvinyl chlorides, polyphenylene ethers, polystyrenes Polyamides, polyolefins, polyketones, polyetherketones, polyimides, polyetherimides, polyethylene terephthalates, polybutylene terephthalates, fluoropolymers, polyesters, polyacetals, liquid crystal polymers, polyethersulfones, phenolic resins, chlorosulfonates, polybutadienes, Polybutylene, polyneoprenes, polynitriles, polyisoprenes, natural rubbers, copolymer rubbers comprising styrene-isoprene-styrenes, styrene-butadiene-styrenes, ethyl ene-propyl enes, ethylene-propylene-diene rubbers, styrene-butadiene rubbers and their copolymers, and mixtures thereof.

20: The composition according to claim 18, wherein at least one polyurethane containing urea group is low-branched or linear.

21: The composition according to claim 20, wherein the at least one polyurethane containing urea group has a degree of branching from 0 to 20%.

22: The composition according to claim 17, wherein the polyurethane containing urea group comprises aliphatic polyisocyanates comprising complementary aliphatic compounds having at least two groups which are reactive to-wards NCO groups, and
wherein the aliphatic polyisocyanate is replaceable by at least one aromatic polyisocyanate by up to 80 wt % based on a total weight of the polyisocyanates.

23: The composition according to claim 17, wherein the composition has an electrical conductivity of at least 2×103 S m−1 at 25° C.

24: The composition according to claim 17, wherein the polymer matrix comprises at least one conductive polymer.

25: The composition according to claim 18, wherein the conductive polymer is selected from a group comprising polyanilines, polypyrroles, polythiophenes, polyethylene dioxythiophenes (PEDOT), poly(p-phenylene-vinylenes), polyacetylenes, polydiacetylenes, polyphenylene sulfides (PPS), polyperinaphthalenes (PPN), polyphthalocyanines (PPhc), sulfonated polystyrene polymers, carbon fiber-filled polymers, and mixtures, derivatives, and copolymers thereof.

26: The composition according to claim 17, wherein the at least one conductive filler is selected from a group comprising carbon nanotubes, carbon fibers, graphite, graphene, conductive soot, metal-coated substrates, elemental metals, metal oxides, metal alloys, and mixtures thereof.

27: The composition according to claim 17, wherein the polyurethane containing urea group comprises at least one diamine component polymerized therein.

28: The composition according to claim 17, comprising:
a) 0.5 to 95 wt % of the at least one conductive filler,
b1) 15 to 99.5 wt % of the at least one polyurethane containing urea group,
b2) 0 to 20 wt % of at least one non-conductive matrix polymer different from b1), and
b3) 0 to 10 wt % of at least one conductive polymer.

29: The composition according to claim 38, further comprising component d) at least one filler and reinforcing material different from components a) to c).

30: The composition according to claim 17, wherein the composition comprises a two-component (2K) polyurethane composition.

31: A method for preparing the composition according to claim 17, comprising:
a) providing the at least one conductive filler; and
b) mixing the at least one conductive filler with the polymers to form the polymer matrix.

32: A method for producing a substrate shielded against electromagnetic radiation comprising the composition according to claim 17, the method comprising:
i) forming the substrate from the composition, or
ii) incorporating the composition into the substrate, or
iii) at least partially coating the substrate with the composition.

33: A method of using the composition of claim 17 for shielding against electromagnetic radiation.

34:The method of claim 33, further comprising using the composition in electronic housings.

35: The composition according to claim 20, wherein at least one polyurethane containing urea group is linear.

36: The composition according to claim 22, wherein the aliphatic polyisocyanate is replaceable by at least one aromatic polyisocyanate by up to 60 wt % based on the total weight of the polyisocyanates.

37: The composition according to claim 27, wherein the at least one diamine component is selected from a group comprising eth-ylenediamine, 1,3-propylenediamine, 1,4-tetramethylenediamine, 1,5-pentamethyldiamine, 1,6-hexamethylenediamine, 2-methyl-1,5-pentamethylenediamine, 1,7-heptamethylenediamine, 1,8-octamethylenediamine, 1,9-nonamethylenediamine, 1,10-diaminododecane, 1,12-diaminododecane, 2,2,4-trimethylhexamethylenediamine, 2,4,4-trimethylhexamethylenediamine, 2,3,3-trimethylhexamethylenediamine, 1,6-diamino-2,2, 4-trimethylhexane, 1-amino-3-aminomethyl-3,5,5-trimethylcyclohexane, 1,4-cyclohexylenediamine, bis-(4-aminocyclohexyl)-methane, isophoronediamine, 1-methyl-2,4-diaminocyclohexane, and mixtures thereof.

38: The composition according to claim 28, further comprising:
c) at least one additive,
wherein the at least one additive is present in an amount of up to 3 wt %.

39: The composition according to claim 28, further comprising:
water, added to 100 wt %.
